(19) United States
(12) Patent Application Publication
(10) Pub. No.: US 2005/0130335 A1
(43) Pub. Date: Jun. 16, 2005

(54) Method of manufacturing master of optical information recording medium, method of manufacturing stamper of optical information recording medium, master and stamper of an optical information recording medium, and optical information recording medium

(76) Inventors: Eiichi Ito, Nishinomiya city (JP); Yuuko Kawaguchi, Ibaraki city (JP)

Correspondence Address: WENDEROTH, LIND & PONACK, L.L.P., 2033 K STREET N. W., SUITE 800, WASHINGTON, DC, 20006-1021, US

(21) Appl. No.: 10/995,156

(22) Filed: Nov. 24, 2004

(30) Foreign Application Priority Data
Dec. 15, 2003 (JP) 2003-416049

(51) Int. Cl. H01L 21/00; H01S 5/00

(52) U.S. Cl. 438/22; 372/43

(57) ABSTRACT

The object of the present invention is to provide a method of manufacturing a master of an optical information recording medium, a method of manufacturing a stamper of an optical information recording medium, a master and a stamper of an optical information recording medium and an optical information recording medium, in which the shape of a pattern of pits and/or a groove remains high-quality by reducing the change of state of an inorganic material when transcribing a predetermined pattern of pits and/or a groove on a side of the stamper, even when an inorganic material is used as an resist.

A method of manufacturing a master 106 of an optical information recording medium for transcribing a predetermined pattern of pits and/or a groove on a stamper of the optical information recording medium, includes forming a resist 102 including an first inorganic material which changes its state with exposure on a substrate 101, forming the pattern of pits and/or a groove on the resist 102 with exposure or development, and forming an inorganic isolating layer 107 on the pattern of pits and/or a groove.

### BACKGROUND OF THE INVENTION

1. Field of the Invention

The present invention relates to a method of manufacturing a master of an optical information recording medium, a method of manufacturing a stamper of an optical information recording medium, a master and a stamper of an optical information recording medium and an optical information recording medium itself.

2. Description of the Prior Art

Generally, an optical information recording medium such as an optical disk is manufactured by using a disk substrate. The disk substrate is produced by an injection molding and the like, using a stamper having a predetermined pattern of pits and/or a groove during the process.

Hereinafter, an example of a method of manufacturing the conventional stamper of an optical information recording medium will be described with reference to FIGS. 5(a) to (e).

During the process of manufacturing the conventional stamper, first as shown in FIG. 5(a), desired patterns such as guide grooves, information pits and the like are formed on a recording master 503, which is made of substrate 501 and a film-like resist 502 thereon, as a latent image 505 with an exposure using a recording light 504 such as a laser light, an electron beam or the like.

Next, as shown in FIG. 5(b), a development is performed on the recording master 503 after the exposure. Consequently, a master 506 having the pattern of pits and/or a groove is produced, on which the desired pattern recorded as the latent image 505 is formed corresponding to pits or lands. Note that, when manufacturing a master for a DVD or a next generation optical information recording medium, exposure using an ultraviolet ray laser or an electron beam, and development using an alkali solution are widely employed.

Then, as shown in FIG. 5(c), a conductive film 507 is formed on the master 506 by using a sputtering method or an electroless deposition method. Next, as shown in FIG. 5(d), a metal layer 508 is formed by plating that uses the conductive film 507. After this, as shown in FIG. 5(e), the metal layer 508 only, or the metal layer 508 with the conductive film 507, is peeled from the master 506, and a shaping process such as back side polishing or punching is performed on the metal layer 508. From the process, a stamper 509a without the conductive film 507 or the stamper 509b with the conductive film 507 is completed. Note that, in some situations, a stamper produced by another process as follows is used: the pattern of pits and/or a groove of the metal layer 508 is transcribed after applying plating or the 2P method more than once onto the metal layer 508 which is peeled from the master 506.

By using the stamper 509a and 509b produced by the processes above, the disk substrate of an optical information recording medium is produced by injection molding or the like. Furthermore, an optical information recording medium is manufactured by using the disk substrate. Here, a positive type photoresist has been described above. However, the above description will also apply to a negative type photoresist, except that the pits and/or a groove on the master are/is reversed.

In the conventional process of manufacturing a stamper of an optical information recording medium, a photoresist made of an organic material has been generally used as the resist 502. However, when such photoresist is used as the resist 502, it is difficult to make sharp edges of the pattern of pits and/or a groove on the photoresist with the exposure. This is because the amount of exposure changes continuously at the boundary of an exposed portion and a non-exposed portion, and the edges of the pattern may incline after removing the resist. Therefore, to form a minute pattern of pits and/or a groove has been a difficult task. Therefore, even when a recording light having the same wavelength as the conventional process is used, a method of manufacturing a stamper in which the resist 502 is made of a thermo-sensitive inorganic material like a phase-changeable material has been proposed that enables the formation of sharper edges of the minute pattern of pits and/or a groove compared to a method using a photoresist made of an organic material (see Japanese Unexamined Patent Publication H10-97738, for example).

A conventional photoresist, which is made of an organic material such as novolac resin and PMMA and used in manufacturing a stamper of an optical information recording medium, has fairly high stability when forming a metal layer of a stamper by plating. When an inorganic material such as a phase-changeable material is used as a resist, edges of the pattern of pits and/or a groove which is formed with a development can be sharpened. However, during the forming of the metal layer by plating, the inorganic material used as a resist changes its state. As just described, if the inorganic material changes its state, it becomes difficult to keep the high-quality shape of the pattern of pits and/or a groove of the resist.

### SUMMARY OF THE INVENTION

The present invention aims to solve the conventional problems mentioned above. The object of the present invention is to provide: a method of manufacturing a master of an optical information recording medium; a method of manufacturing a stamper of an optical information recording medium; a master and a stamper of an optical information recording medium; and an optical information recording medium, in which the shape of the pattern of pits and/or a groove is kept favorable by reducing the change of state of the inorganic material when transcribing the predetermined pattern of pits and/or a groove on a side of the stamper.

In a first method of manufacturing a master of an optical information recording medium of the present invention, a master of an optical information recording medium is manufactured by the following processes: a resist including an inorganic material which changes its state with exposure is formed on a substrate; a pattern of pits and/or a groove is formed on the resist with the exposure and development on the resist; and an isolating layer is formed on the pattern of pits and/or a groove. In other words, in the method of manufacturing the stamper, the isolating layer is formed between the resist and a conductive film.

The isolating layer enables the reduction of a chemical reaction between the resist and the conductive film by physically separating them.

In addition, if the isolating layer contains an inorganic material with low electrical conductivity, the resist and the conductive film can be electrically isolated (almost an insulated state), and a decomposition reaction of the resist itself promoted by electronic activity and also a reaction between the resist and the conductive film can be reduced. Note that, the inorganic material with low electrical conductivity preferably has lower electrical conductivity than the resist. In addition, when an organic material is used for the isolating layer, to form a layer as a solid on the master is difficult. In other words, a sharp pattern of pits and/or a groove on the stamper cannot be formed because a film of an organic material with a liquid state is formed. On the other hand, when the inorganic material is used instead, the sharp pattern of pits and/or a groove is easily maintained because an evaporation method, particularly a sputtering method, can be used.

In a method of manufacturing a master and a stamper of the present invention, vacuum processing may be applied while forming the isolating layer. As the vacuum processing, for example, a vacuum evaporation method, a sputtering method, a chemical vapor deposition method or the like can be used. Particularly, the sputtering method is more preferable because high adhesiveness on the resist, to reduce dust and to form a stable film can easily be performed.

When materials which contain a material having a good peeling property are used for the isolating layer, such as fluorides or Diamond-Like Carbon, the method of the present invention can be performed favorably because residues of the inorganic isolating layer can be reduced on the stamper.

When materials which contain silicon dioxide are used for the isolating layer and materials which contain gold or elements of the platinum group for the conductive film, the method of the present invention can be performed favorably not only because residues of the inorganic isolating layer on the stamper can be reduced, but also because dissolving the residues of the isolating layer remaining on the stamper becomes possible.

When materials which contain, for example: alkali-soluble materials like tungsten oxide, niobium oxide, tin oxide, molybdenum oxide, silicon and the like; water-soluble materials like sodium chloride, ferric chloride, potassium iodide, rubidium chloride and the like; and acid-soluble materials like tin oxide and copper chloride, the method of the present invention can be performed favorably because dissolving the residues of the isolating layer remaining on the stamper becomes possible.

The thickness of the isolating layer is preferably 5 nm or more and 150 nm or less, and further preferably 15 nm or more and 150 nm or less.

A second method of manufacturing a master of an optical information recording medium of the present invention is that; in the first method of manufacturing a master and a stamper of an optical information recording medium of the present invention, a peeling layer is formed on the inorganic isolating layer during manufacturing of the master, and the peeling layer is formed between the isolating layer and the conductive film during manufacturing of the stamper. With the peeling layer, the stamper can be manufactured favorably because the residues can easily be dissolved and eliminated even when they appear on the stamper. As the peeling layer, various inorganic materials or organic materials may be used, which are highly soluble in acid, alkali, water or an organic solvent.

The total thickness of the isolating layer and the peeling layer made of an inorganic material is preferably 150 nm or less, and the thickness of the isolating layer is preferably 5 nm or more, or 15 nm or more.

In addition, the thickness of the peeling layer made of an organic material is preferably 60 nm or less.

In either method of manufacturing the master and the stamper, the inorganic materials comprising the resist preferably contain, for example, germanium, tellurium, antimony, selenium, molybdenum, tungsten, titanium and the like, or a compound of these elements as a main component. In addition, inorganic materials of the resist may contain, gold, platinum, copper, palladium, silicon or the like.

In addition, although an electroless deposition is more preferable to form the conductive film, a vacuum process such as a sputtering can also be used.

According to a method of manufacturing a master of an optical information recording medium of the present invention, even when an inorganic material is used as a resist, a favorable shape of the pattern of pits and/or a groove can be maintained by reducing the change of state of the material during a process of transcribing the predetermined pattern of pits and/or a groove on a side of the stamper. Thus, the favorable plating can be performed, and the inorganic material, which has not been suitable for plating in the past because it changes its state during exposure, becomes available as a resist.

### BRIEF DESCRIPTION OF THE DRAWINGS

FIG. 1 shows a method of forming the pattern of Embodiment 1 of the present invention.

FIG. 2 shows a method of exposure when forming the pattern of Embodiment 1 of the present invention.

FIG. 3 shows the height of a pit or a groove when forming the pattern of Embodiment 1 of the present invention.

FIG. 4 shows a method of forming the pattern of Embodiment 2 of the present invention.

FIG. 5 shows a method of forming the pattern of the conventional technique.

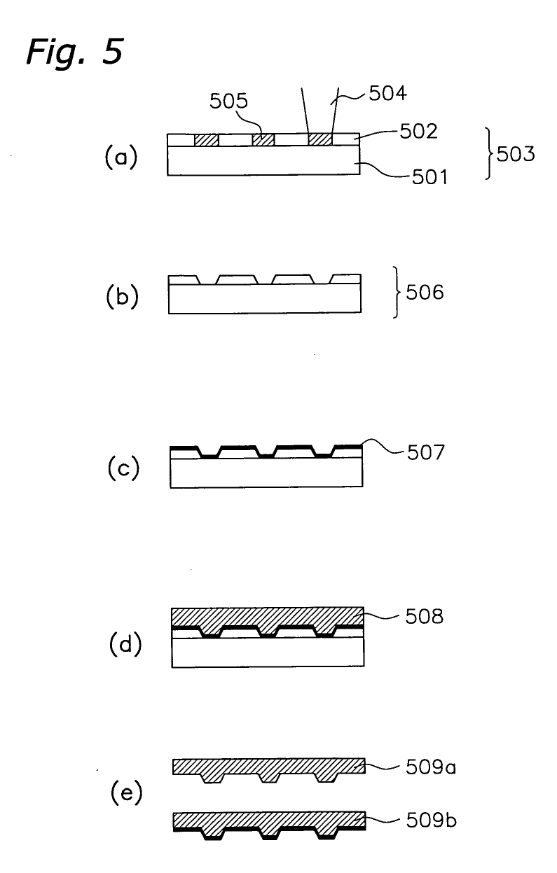

### DESCRIPTION OF THE PREFERRED EMBODIMENTS

Hereinafter, embodiments of the present invention will be explained in detail with reference to the figures.

(Embodiment 1)

(1) Overview of a Manufacturing Method

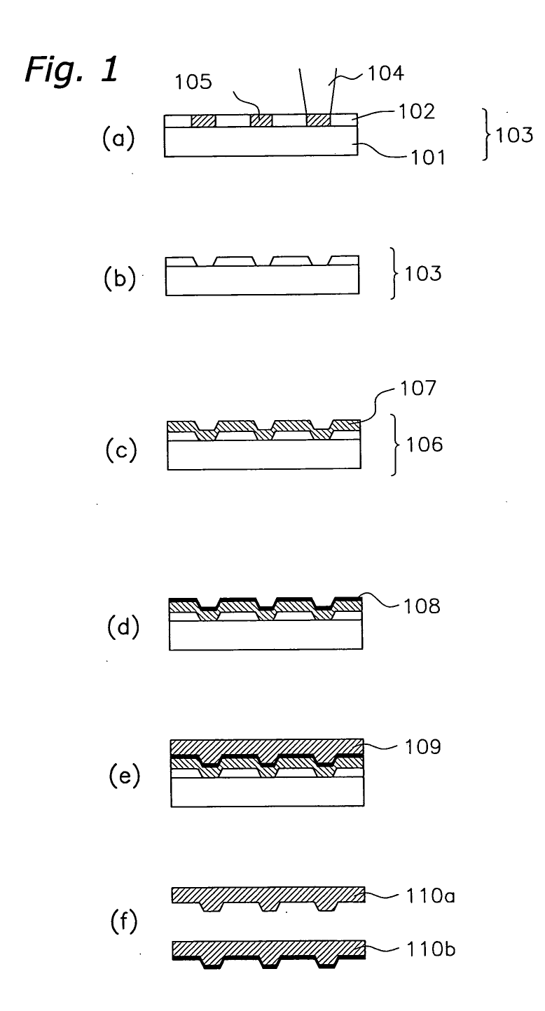

Hereinafter, an overview of a method of manufacturing a stamper of an optical information recording medium of Embodiment 1 of the present invention will be described with reference to FIGS. 1(a) to (f).

First, as shown in FIG. 1(a), a desired pattern such as guide grooves, information pits and the like are formed on a recording master 103 as a latent image 105 with an exposure using a recording light 104 such as a laser light, an electron beam or the like. As the recording master 103, a film-like resist 102 made of an inorganic material which changes its state with the exposure is formed on a substrate 101 (this is called an exposure process).

Next, as shown in FIG. 1(b), by performing development on the recording master 103 after the exposure, the minute pattern of pits and/or a groove is formed on the recording master 103 and the desired pattern recorded as the latent image 105 are formed corresponding to the pits or the lands (this is called a development process).

Then, as shown in FIG. 1(c), a master 106 is produced by forming an inorganic isolating layer 107 on the minute pattern of pits and/or a groove on the recording master 103 (this is called a process of forming an inorganic isolating layer).

Further, as shown in FIG. 1(d), a conductive film 108 is formed on the inorganic isolating layer 107 by the electroless deposition method (this is called a process of forming a conductive film). Note that, the conductive film 108 can also be formed by the sputtering method.

And as shown in FIG. 1(e), a metal layer 109 is formed on the conductive film 108 by plating that uses the conductive film 108 (this is called a process of forming a metal layer).

After this, as shown in FIG. 1(f), the metal layer 109 only, or the metal layer 109 with the conductive film 108, is peeled from the master 106, and a shaping process such as back side polishing or punching is performed on the metal layer 109 (this is called a peeling process). From the process, a stamper 110a without the conductive film 108 or a stamper 110b with the conductive film 108 is completed, on which the pattern of pits and/or a groove of the master 106 is transcribed. Furthermore, a substrate is produced by injection molding using the stamper, and an optical information recording medium is produced by using the substrate.

If the method of the present invention is employed, even when a recording light having almost the same wavelength as the conventional one is used for a photoresist made of an organic material during an exposure, a stamper with a higher recording density than a conventional one, and furthermore an optical information recording medium, can be produced.

(2) Detail Description of the Manufacturing Method

Hereinafter, the method of manufacturing a stamper of an optical information recording medium of Embodiment 1 of the present invention will be described in more detail.

As the substrate 101 of the recording master 103 which is exposed during the exposure process (see FIG. 1(a)), a substrate made of various glasses, silicon or resins is used, for example. As a material of a resist 102 formed on the substrate 101, an inorganic material which changes its state with the exposure is used, for example, germanium, tellurium, antimony, selenium, molybdenum, tungsten, titanium and a material which primarily contains an oxide compound or the like of these elements. Note that, if these inorganic materials contain noble metals such as gold, platinum group, silver and copper, or contain silicon dioxide or the like, the ratio of the remaining film during the development process can be improved, and these inorganic materials are suitable for the method of the present invention. Here, the resist 102 made of an inorganic material which changes its state with the exposure is formed on the substrate 101 by a sputtering method, a vacuum evaporation method, a spin coating method or the like, for example. Particularly, by using the sputtering method, a uniform resist 102 which attracts less dust which is suitable for the method of the present invention can be produced favorably. Note that, the recording master 103 may include structure elements other than the above such as an interface layer or a reflective layer, as long as the master 103 keeps the structure described above.

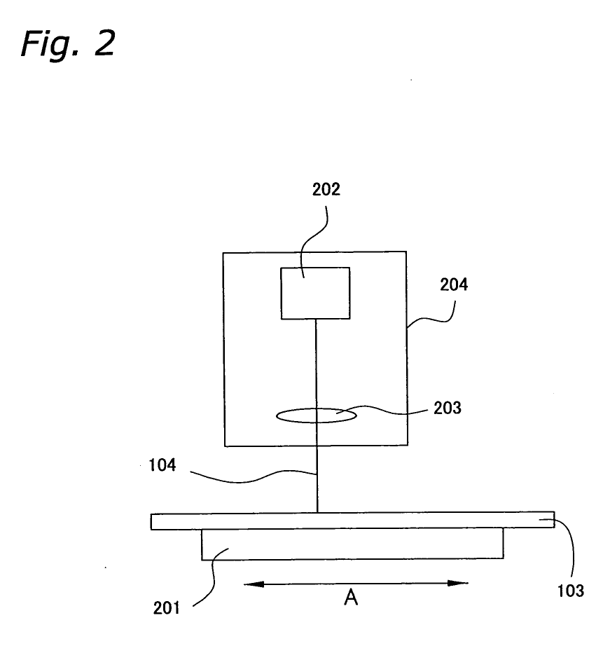

Next, with reference to FIG. 2, a method of exposing the resist 102 on the recording master 103, in other words, a method of recording a pattern on the recording master 103 is described. As shown in FIG. 2, the recording master 103 is placed on a rotation table 201 and rotated with the table 201. A recording light 104 emitted from a light source 202 is focused by a lens 203 onto a surface of the recording master 103. Note that, if necessary, the recording light 104 may be modulated and deflected in the recording light source 202. During the recording process, a recording head 204 and the rotation table 201 are moved in parallel relative to each other, as shown by arrow A. Thus, a spiral-like recording is performed on the recording master 103, and the desired pattern is formed as the latent image 105 described above. As the recording light 104, a laser light or an electron beam can be used. On the recording master 103 on which the desired pattern is formed as the latent image 105, the etching rate is different in each area where its state has changed with the exposure such as a phase change and the like (hereinafter, referred to as “a state-changed area”) and where its state has not changed because the exposure has not been applied (hereinafter, referred to as “a state-unchanged area”).

Thus, during the development process (see FIG. 1(b)), the recording master 103 is developed by etching using the difference of the etching rate. Dry etching such as reactive ion etching, or wet etching using acid or alkali, are examples of such the etching; however, any methods are available if the etching rate is different between the state-changed area and the state-unchanged area. With such development process, the recording master 103 of the optical information recording medium having the pattern of pits and/or a groove is produced.

During the forming process of the inorganic isolating layer (see FIG. 1(c)), for example, an inorganic material such as a fluoride, an oxide, a nitride, Diamond-Like Carbon (hereinafter, described as DLC) or the like is formed on the recording master 103 as a thin film by using for example, the sputtering method, the vacuum evaporation method, the chemical vapor deposition method (hereinafter, described as CVD) or the like. Thus, the master 106 is produced, which includes the substrate 101, the developed resist 102 (the recording master 103) and the inorganic isolating layer 107. With the inorganic isolating layer 107, because the resist 102 can be isolated from the conductive film 108 or the metal layer 109, the reaction between the resist and other layers, as well as the state of the resist 102 changing, can be prevented. Furthermore, residues of the inorganic isolating layer 107 on the stamper 110 can be reduced.

Note that, various materials other than above can be used as inorganic materials; however, inorganic materials which satisfy the following requirements are preferable for Embodiment 1 of the present invention.
(Requirement 1) Having low electrical conductivity and having high resistance to electrical decomposition
(Requirement 2) Having a good peeling property relative to the conductive film 108
(Requirement 3) Ability to dissolve in a solvent which does not corrode the surface of the conductive film 108

Requirement 1 is necessary when a voltage is applied by plating to prevent the inorganic material from reacting with the conductive film 108 or with the metal layer 109 which is formed by plating, or from electrical decomposition. For example, because a fluoride, an oxide, a nitride and the like are extremely stable, these materials can favorably be used in the methods of the present invention.

Requirement 2 is effective to reduce residues of the inorganic material which remain on the stamper 110b when manufacturing the stamper 110b with the conductive film 108.

Requirement 3 is effective to eliminate the residues of the inorganic material remaining on the stamper 110b without corroding the stamper 110b by using for example alkali, water and acid when producing the stamper 110b with the conductive film 108. The residues occur due to the use of an inorganic material being soluble in the solvent which does not corrode the surface of the stamper 110b, such as alkali and water (acid can also be used if the surface of the stamper 110b is a material having high acid resistance such as gold or platinum group).

Note that, as described above, Requirement 2 and Requirement 3 are necessary to reduce or eliminate the residues when manufacturing the stamper 110b with the conductive film 108, and not necessary when manufacturing the stamper 110a without the conductive film 108.

As specific materials satisfying these requirements, following materials are suitable for requirement 1: fluorides such as magnesium fluoride or lanthanum fluoride; oxides such as silicon dioxide or molybdenum oxide; nitrides such as silicon nitride or aluminum nitride; and compounds of these materials.

As materials satisfying requirement 2, the following materials are suitable for the present invention; fluorides such as magnesium fluoride, lanthanum fluoride or calcium fluoride; DLC; and silicon dioxide (note that, for the conductive film 108, a material which is less adhesive to silicon dioxide needs to be chosen; such as gold, a platinum group, copper or aluminum). When gold is used as a conductive film, the following materials have good peeling properties and are favorable for the method of the present invention: for example a titanium oxide, an aluminum oxide, a bismuth oxide or a tin oxide. In the inorganic materials which satisfy Requirement 2, not only the residues of the inorganic isolating layer 107 on the stamper 110b are reduced, but also elimination of the residues by dissolving becomes possible when the residues of the inorganic isolating layer 107 on the stamper 110b appears.

As materials satisfying requirement 3, the following materials are suitable for the method of the present invention: an alkali-soluble material such as tungsten oxide, niobium oxide, tin oxide, molybdenum oxide or silicon; a water-soluble material such as sodium chloride, ferric chloride, potassium iodide or rubidium chloride; and an acid-soluble material such as tin oxide (for tin oxide, when a surface of the stamper is made of materials having high acid resistance such as gold or platinum group) or copper chloride. Needless to say, other than the materials above, materials which satisfy each of the Requirements can be used in the method of the present invention.

Note that, materials made by mixing the materials satisfying Requirement 2 or Requirement 3 described above with the materials satisfying Requirement 1 can also be used.

For a method of forming the inorganic isolating layer 107 made of the inorganic material above, any method can be used if the method can realize the thickness and uniformity requirements described below. Note that, for the method of forming the inorganic isolating layer 107, the sputtering method is preferable because high adhesiveness on the resist 102, to reduce dust and to form a stable film, can easily be performed. However, because DLC is not suitable for the sputtering method, the inorganic isolating layer 107 can be formed favorably by using CVD.

In this situation, conditions for the sputtering method or CVD are arbitrarily chosen. In addition, when the sputtering method is used to form the inorganic isolating layer 107, the following methods are available: sputtering using an inert gas such as argon or xenon, as well as using a target such as silicon dioxide or silicon nitride having a predetermined composition; sputtering using a plurality of targets; and reactive sputtering using targets (also can be a single target) in which fluorine, oxygen or nitrogen and the like are lower than the predetermined composition. The reactive sputtering may be performed, for example, by mixing an inert gas such as argon or xenon with fluorine, oxygen or nitrogen. For example, in order to form the inorganic isolating layer 107 of silicon dioxide, RF sputtering may also be performed under power of 400W and a furnace pressure of 2 mTorr by using a target of silicon dioxide and introducing argon in a high-vacuum state. Needless to say, the present invention is not limited to the above-mentioned furnace pressure and output.

As for a thickness of the inorganic isolating layer 107, the two conditions described below have to be satisfied.

(First Condition)

When plating the metal layer 109, the thickness needs to be enough to reduce chemical reaction of the resist 102 only, or a chemical reaction between the resist 102 and the conductive film 108 or between the resist 102 and the metal layer 109.

(Second Condition)

After forming the inorganic isolating layer 107, the thickness is enough to form the pattern of pits and/or a groove having a desired height and shape on a surface of the inorganic isolating layer 107.

### EXAMPLE 1

First, Example 1 of the first condition is described.

In Table 1, the results of producing the stamper 110 and measuring the non-failure rate of plating in four cases where a different resist 102 and a different inorganic isolating layer 107 were used. Here, as the resist 102, two resists (a resist A and a resist B) were used which were made of Te oxide having low stability for plating the metal layer 109. As materials of the inorganic isolating layer 107, silicon dioxide and tungsten oxide were used. In addition, variations of plating resistance of the resist 102 were measured when the thickness of the inorganic isolating layer 107 was changed in a range of 0 to 15 nm. The plating resistance for each case was shown as the number of favorable plating results out of ten plating trials.

TABLE 1
Non-failure rate of plating (Number of non-failure per 10 trails)

| Thickness of inorganic isolating layer [nm] | | 0 | 3 | 5 | 10 | 15 |
|---|---|---|---|---|---|---|
| Inorganic isolating layer | resist A | 0 | 0 | 2 | 8 | 10 |
| Silicon dioxide | resist B | 4 | 7 | 9 | 10 | 10 |
| Inorganic isolating layer | resist A | 0 | 0 | 3 | 9 | 10 |
| Tungsten oxide | resist B | 4 | 8 | 8 | 10 | 10 |

As is clear from Table 1, when the thickness of the inorganic isolating layer 107 was 5 nm or more, the plating resistance of the resist B definitely improved, which had fairly high plating resistance, and particularly when the thickness is 15 nm or more, the plating resistance of either of the resist A and the resist B further improved. Note that, even when the inorganic isolating layer 107 was evaluated by using other resists having low plating resistance, the improvement was also definitely achieved, and particularly when the thickness was 15 nm or more, further improvement could be achieved. Note that, the thickness of the inorganic isolating layer 107 is considered to have no upper limit to satisfy Requirement 1.

### EXAMPLE 2

Next, Example 2 of the second condition is described.

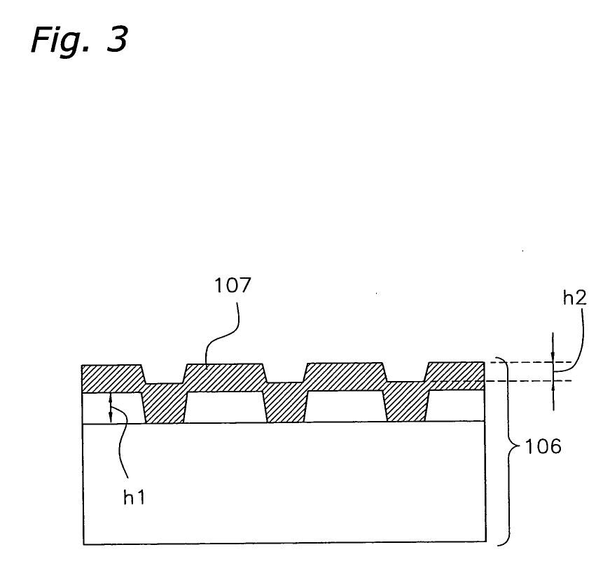

Table 2 shows the results of the height of a pit or a groove on the surface of the inorganic isolating layer 107, relative to the height of the pattern of pits and/or a groove of the two masters 106 (Here, 35 nm and 90 nm). The thickness of the inorganic isolating layer 107 is changed in a range of 15 to 240 nm. The height of the pattern of pits and/or a groove shows a height h1 of a pit or a groove before forming the isolating layer, as shown in FIG. 3. In addition, the thickness of the inorganic isolating layer 107 shows the thickness of the land in the pattern of pits and/or a groove of the inorganic isolating layer 107. Here, the track pitch of the master 106 is 320 nm. In addition, on the master 106, short and long pit sequences of which the shortest pit length is approximately 100 nm are formed as the pattern of pits and/or a groove. As a material of the inorganic isolating layer 107, silicon dioxide is used.

Note that, in FIG. 3, the height h1 of a pit or a groove before forming the isolating layer shows the height of the pattern of pits and/or a groove before forming the inorganic isolating layer of the master 106, and the height h2 of a pit or a groove after forming the isolating layer shows the height of the pattern of pits and/or a groove of the surface of the inorganic isolating layer 107.

TABLE 2
Height of a pit or a groove after forming inorganic isolating layer

| | | | | | | | | | |
|---|---|---|---|---|---|---|---|---|---|
| Thickness of inorganic isolating layer [nm] | 15 | 30 | 60 | 90 | 120 | 150 | 180 | 210 | 240 |
| Height of a pit or a groove before forming | 34 | 34 | 36 | 33 | 34 | 33 | 30 | 28 | 25 |
| inorganic isolating layer: 35 nm | | | | | | | | | |
| Height of a pit or a groove before forming | 89 | 91 | 88 | 89 | 87 | 87 | 82 | 76 | 70 |
| inorganic isolating layer: 90 m | | | | | | | | | |

As is clear from Table 2, as the thickness of the inorganic isolating layer 107 increased, the difference between the height h1 before forming the isolating layer and the height h2 after forming the isolating layer gradually increased. However, because a measurement error of the height measurement is between 2 and 3 nm, when the thickness of the inorganic isolating layer 107 is 150 nm or less, the height h1 before forming the isolating layer and the height h2 after forming the isolating layer may be said to be the same in essence. From the results, when the thickness of the inorganic isolating layer 107 is 150 nm or less, particularly favorable effects of the present invention can be achieved. However, even when the thickness of the inorganic isolating layer 107 is over 150 nm, it is also available in other applications as long as the change of the shape of pits and/or a groove due to forming of the inorganic isolating layer 107 is acceptable, and the present invention is still effective. In addition, in order to control the height h2 after forming the isolating layer, the height h1 before forming the isolating layer and the height h2 after forming the isolating layer needs to be changed intentionally, and the inorganic isolating layer 107 having a thickness of 150 nm or more can be used.

From the above-mentioned measurement results, the thickness of the inorganic isolating layer 107 is preferably 5 nm or more and 150 nm or less, and particularly 15 nm or more and 150 nm or less. The above are the descriptions of Example 1 and 2.

During the process of forming the conductive film, on the inorganic isolating layer 107 of the master 106, the conductive film 108 made of conductive materials such as nickel or copper is formed by an electroless deposition method. Note that, by using the sputtering method or the vacuum evaporation method, the conductive film 108 made of conductive materials such as nickel, copper or gold can also be formed. During the process of forming the metal layer, the conductive film 108 is used as an electrode when forming the metal layer 109.

During the process of forming the metal layer, the metal layer 109 is formed on the conductive film 108 by performing plating such as a nickel electroforming plating. Note that, when an electroless deposition method is used for forming the conductive film 108 during the process of forming the conductive film, the residues of the inorganic isolating layer 107 remaining on the stamper 110b can be reduced, because the adhesiveness between the resist 102 and the conductive film 108 becomes low compared to the sputtering method or the vacuum evaporation method.

During a peeling process, the metal layer 109 only or the metal layer 109 with the conductive film 108 is peeled from the master 106, and a shaping process such as back side polishing or punching is performed on the metal layer 106. With these processes, the stampers 110a and 110b are completed. Note that, when only the metal layer 109 is peeled from the master 106 during the peeling process, the peeling is easily performed by performing surface reforming like an oxygen plasma treatment on the conductive film 108 before the process of forming the metal layer.

On the other hand, when the metal layer 109 and the conductive film 108 are peeled from the master 106 as an integrated unit, a few residues of the inorganic isolating layer 107 may remain on the conductive film 108 (on the stamper 110b). In a situation like this, an inorganic material which satisfies Requirement 2 or Requirement 3 can be used as the inorganic isolating layer 107. If a material satisfying Requirement 2 is used, it is very effective to reduce the residues. Even when residues remain, the residues can easily be peeled and eliminated by using an adhesive sheet and the like. If a material satisfying Requirement 3 is used, the residues can be dissolved and eliminated by using the following solvents in which the material used as the inorganic isolating layer 107 is soluble: alkali such as aqueous sodium hydrate solution, aqueous potassium hydrate solution and tetramethyl ammonium hydroxide (TMAH); water; and an acid such as hydrochloric acid, for example. Note that, when an acid is used for eliminating residues, a material having high acid resistance such as gold can be used as the conductive film 108 beforehand, because the acid may corrode the surface of the stamper 110b. In addition, as a material which combines both Requirement 2 and Requirement 3, silicon dioxide for the inorganic isolating layer 107 and noble metal which has high acid resistance such as gold or platinum group for the conductive film 108 are also effective to reduce the residues of the inorganic isolating layer 107. In this situation, not only the silicon dioxide and the noble metal are very effective to reduce the residues because they have good peeling properties against each other, but are also effective to eliminate the residues by dissolving the silicon dioxide. This is because the surface of the stamper is covered by gold and the like having a high acid resistance, and by using for example fluorinated acid having concentration of approximately 5%, the residues can be eliminated. Note that, other concentrations of fluorinated acid can also be used.

As mentioned above, conventionally, to perform plating onto the inorganic material which changes its state with exposure has been difficult. However, according to the method of manufacturing a stamper of an optical information recording medium of Embodiment 1 of the present invention, such inorganic material becomes available as a resist. Consequently, compared to the method of manufacturing a stamper using a conventional photoresist made of an organic material, a stamper having higher recording density and furthermore an optical information recording medium can be manufactured, even when a light source having a similar wavelength to a conventional one is used. This is because the shape of the pattern of pits and/or a groove can be kept in a favorable state while reducing changes of the state of the inorganic material when transcribing the predetermined pattern of pits and/or a groove on the side of the stamper 110.

(Embodiment 2)

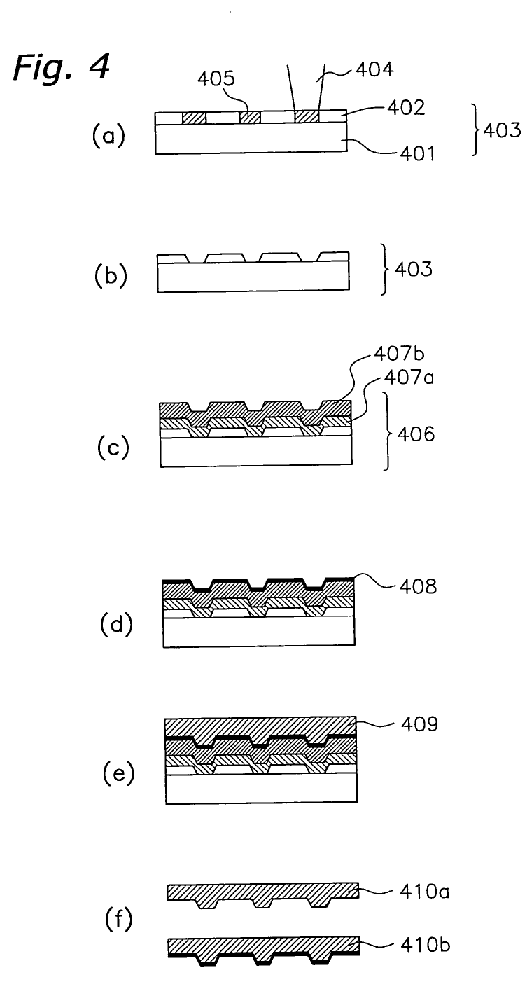

Hereinafter, with reference to FIG. 4, Embodiment 2 of the present invention is described. Note that, a method of manufacturing a master of an optical information recording medium of Embodiment 2 is the same as that of Embodiment 1, except for newly forming a peeling layer 407b on an inorganic isolating layer 407a, and placing the peeling layer 407b between the inorganic isolating layer 407a and a conductive film 408 during the process of manufacturing the stamper. Therefore, hereinafter, in order to avoid any overlapping explanations, the parts different from Embodiment 1 are mainly described with reference to FIGS. 4(a) to (f).

In a method of manufacturing a stamper of Embodiment 2, an exposure process and development processes are the same as Embodiment 1. During the process of forming an inorganic isolating layer, which is the same as Embodiment 1, the peeling layer 407b is formed after the inorganic isolating layer 407a is formed. As a result, the master 406 is produced.

The process of forming the peeling layer 407b is now described in more detail. The peeling layer 407b is made of materials being soluble in a solvent: such as alkali, organic solvent, water and acid (in acid, a surface of the stamper needs to be made of materials having high acid resistance such as gold or platinum group) which do not damage the stamper 410. If those materials are used when producing the stamper 410b with the conductive film 408, even when residues of the inorganic material occur on the stamper 410b, the residues are effectively eliminated without damaging the stamper 410b by using the above-mentioned solvent. As the peeling layer 407b, the following inorganic materials are suitable for the present invention; alkali-soluble materials such as tungsten oxide, niobium oxide, tin oxide, molybdenum oxide or silicon; water-soluble materials such as sodium chloride, ferric chloride, potassium iodide or rubidium chloride; acid-soluble materials such as tin oxide and copper chloride; and materials which are soluble in the organic solvent such as ferric chloride or potassium iodide. As an organic material, materials being soluble in the following solvents are suitable for the present invention: an alkali such as phenol resin or an acrylate resin; water, acid; and organic solvent. Needless to say, other than the materials above, any of the following materials being soluble in a solvent which does not damage the stamper are suitable: alkali, organic solvent, water, acid (in acid, when a surface of a stamper is made of materials having high acid resistance such as gold or platinum group) and the like.

When inorganic materials are used for the peeling layer 407b, the structure is similar to that described in Embodiment 1 in essence. However, to eliminate the residues on the stamper 410b, the method here is more effective than the method in Embodiment 1. This is because in Embodiment 2, the function of the inorganic isolating layer 107 of Embodiment 1 is divided into the two functions of the inorganic isolating layer 407a and the peeling layer 407b. Thus, a material which functions highly as the isolating layer but its residues on the stamper 410b become a problem, can be used as the inorganic isolating layer 407a, or a material which is highly soluble in alkali but does not function well as an isolating layer can be used as the peeling layer 407b. The processes of forming the inorganic isolating layer 407a and the peeling layer 407b are the same as the method of forming the inorganic isolating layer 107 of Embodiment 1. As for the thickness of the inorganic isolating layer 407a and the peeling layer 407b, from the results of the experiments described in Example 1 and Example 2, the thickness of the inorganic isolating layer 407a is preferably 5 nm or more, and the total thickness of the inorganic isolating layer 407a and the peeling layer 407b is preferably 150 nm or less. Furthermore, the thickness of the inorganic isolating layer 407a is more preferably 15 nm or more, and the total thickness of the inorganic isolating layer 407a and the peeling layer 407 is more preferably 150 nm or less.

When an organic material is used for the peeling layer 407b, the method of forming the inorganic isolating layer 407a is the same as the method of forming the inorganic isolating layer 107 of Embodiment 1, and to form the peeling layer 407b, the spin coating or the vacuum evaporation method can be used. From the results of the experiments described in Example 1 and Example 2, the thickness of the inorganic isolating layer 407a is preferably 5 nm or more and 150 nm or less, and more preferably 15 nm or more and 150 nm or less. When the peeling layer 407b made of the organic materials is formed by either the spin coating method or the vacuum evaporation method, the pattern of pits and/or a groove on the inorganic isolating layer 407a, of which the pattern of pits and/or a groove on the recording master 403 is reflected, is formed as a blunt (round-edged) pattern of pits and/or a groove on the peeling layer 407b. Here, to investigate the degree of bluntness of the pattern of pits and/or a groove, variations of the surface height of a pit or a groove when the thickness of the peeling layer 407b changes was measured. Table 3 shows the results of using the peeling layer 407b formed by the spin coating method, and Table 4 shows the results of using the peeling layer 407b formed by the vacuum evaporation method. The surface heights of a pit or a groove of the inorganic isolating layer during the measurement were 35 nm and 90 nm.

TABLE 3
Surface height of a pit or a groove of organic peeling layer:
Spin coating method

| | | | | | | |
|---|---|---|---|---|---|---|
| Thickness of organic peeling layer [nm] | 5 | 10 | 20 | 40 | 60 | 80 |
| Surface height of a pit or a groove | 25 | 18 | 17 | 15 | 12 | 7 |
| of inorganic isolating layer: 35 nm | | | | | | |
| Surface height of a pit or a groove | 53 | 49 | 47 | 41 | 36 | 29 |
| of inorganic isolating layer: 90 nm | | | | | | |

TABLE 4
Surface height of a pit or a groove of organic peeling layer:
Vacuum evaporation method

| | | | | | | |
|---|---|---|---|---|---|---|
| Thickness of organic peeling layer [nm] | 5 | 10 | 20 | 40 | 60 | 80 |
| Surface height of a pit or a groove | 35 | 33 | 29 | 25 | 22 | 16 |
| of inorganic isolating layer: 35 nm | | | | | | |
| Surface height of a pit or a groove | 82 | 71 | 68 | 63 | 58 | 41 |
| of inorganic isolating layer: 90 nm | | | | | | |

From the results of Table 3 and Table 4, it can be seen that as the thickness of the peeling layer 407b becomes thick, the height of a pit or a groove of the peeling layer 407b becomes small. In other words, the pattern of pits and/or a groove becomes blunt. In addition, when the thickness of the peeling layer 407b is 80 nm or more, the thickness itself is not uniform. Therefore, the thickness of the peeling layer 407b is preferably 60 nm or less by using either the spin coating method or the vacuum evaporation method. However, as described above, as the thickness of the peeling layer 407b becomes thick, the degree of bluntness of the pattern of pits and/or a groove becomes large. Thus, if the pattern of pits and/or a groove on the recording master 403 needs to be reproduced as completely as possible on the stamper 410, it is preferable to make the thickness of the peeling layer 407b as thin as possible, or to use the peeling layer 407b made of the inorganic material.

In the method of manufacturing a stamper, the process of forming the conductive film, the process of forming the metal layer and the peeling process are similar to Embodiment 1. In addition, the process of eliminating residues on the stamper 410b is similar to Embodiment 1 except for using a solvent suitable for the peeling layer 407b. Note that, when organic materials are used for the peeling layer 407b, just as DLC is used in Embodiment 1, oxidization such as the oxygen plasma treatment is effective for the elimination.

The stampers 410a and 410b are completed through each of the above-mentioned processes.

Hereinabove, according to the method of manufacturing a stamper of an optical information recording medium of Embodiment 2 of the present invention, an inorganic material, which was not conventionally suitable for plating because the material changes its state with exposure, can be used as the resist. Consequently, compared to the method of manufacturing a stamper using a conventional photoresist made of an organic material, even when a light source having a similar wavelength to the conventional one is used, a stamper with higher recording density and furthermore an optical information recording medium can be manufactured.

In addition, compared to the method of manufacturing a stamper without using the peeling layer of Embodiment 1, a stamper on which the residues are easily eliminated can be manufactured.

A method of manufacturing a master of an optical information recording medium, a method of manufacturing a stamper of an optical information recording medium, a stamper of an optical information recording medium, and an optical information recording medium according to the present invention are effective to enable the performing of a favorable plating process in which a pattern of pits and/or a groove, which is produced by using a resist of an inorganic material, are transcribed by plating. Particularly, the present invention is useful for micromachining processes in the order of nanometers having a process of transcribing a pattern by plating that is formed by photolithography, such as manufacturing of an optical information recording medium or a micro machine.

1. A method of manufacturing a master of an optical information recording medium for transcribing a predetermined pattern of pits or a groove on a stamper of the optical information recording medium, comprising:
forming a resist including a first inorganic material on a substrate, wherein the material changes its state with exposure;
forming the pattern of pits or a groove on the resist with exposure and development; and
forming an isolating layer on the pattern of pits or a groove.

2. The method of manufacturing a master of an optical information recording medium of claim 1, wherein the isolating layer is made of a second inorganic material with low electrical conductivity.

3. The method of manufacturing a master of an optical information recording medium of claim 2, wherein the isolating layer contains a fluoride as the second inorganic material.

4. The method of manufacturing a master of an optical information recording medium of claim 2, wherein the isolating layer contains Diamond-Like Carbon as the second inorganic material.

5. The method of manufacturing a master of an optical information recording medium of claim 2, wherein the isolating layer contains silicon dioxide as the second inorganic material.

6. The method of manufacturing a master of an optical information recording medium of claim 2, wherein the isolating layer contains an alkali-soluble material as the second inorganic material.

7. The method of manufacturing a master of an optical information recording medium of claim 6, wherein the isolating layer contains at least any one of tungsten oxide, niobium oxide, tin oxide, molybdenum oxide and silicon as the second inorganic material.

8. The method of manufacturing a master of an optical information recording medium of claim 2, wherein the isolating layer contains a water-soluble material as the second inorganic material.

9. The method of manufacturing a master of an optical information recording medium of claim 8, wherein the isolating layer contains at least any one of sodium chloride, ferric chloride, potassium iodide and a rubidium chloride as the second inorganic material.

10. The method of manufacturing a master of an optical information recording medium of claim 2, wherein the isolating layer contains an acid-soluble material as the second inorganic material.

11. The method of manufacturing a master of an optical information recording medium of claim 1, wherein the isolating layer is formed by a sputtering method.

12. The method of manufacturing a master of an optical information recording medium of claim 1, wherein a thickness of the isolating layer is 5 nm or more and 150 nm or less.

13. The method of manufacturing a master of an optical information recording medium of claim 12, wherein the thickness of the isolating layer is 15 nm or more and 150 nm or less.

14. The method of manufacturing a master of an optical information recording medium of claim 1, wherein the first inorganic material contains germanium, tellurium, antimony, selenium, molybdenum, tungsten, titanium and at least any one of the compounds of these elements.

15. A method of manufacturing a master of an optical information recording medium of claim 1, wherein a peeling layer is formed on the isolating layer.

16. The method of manufacturing a master of an optical information recording medium of claim 15, wherein the peeling layer contains an alkali-soluble material.

17. The method of manufacturing a master of an optical information recording medium of claim 15, wherein the peeling layer contains a water-soluble material.

18. The method of manufacturing a master of an optical information recording medium of claim 15, wherein the peeling layer contains an acid-soluble material.

19. The method of manufacturing a master of an optical information recording medium of claim 15, wherein the peeling layer is made of an inorganic material.

20. The method of manufacturing a master of an optical information recording medium of claim 15,
wherein both the isolating layer and the peeling layer are made of an inorganic material, and
a total thickness of the isolating layer and the peeling layer is 150 nm or less, and the thickness of the isolating layer is 5 nm or more.

21. The method of manufacturing a master of an optical information recording medium of claim 20, wherein the thickness of the isolating layer is 15 nm or more.

22. The method of manufacturing a master of an optical information recording medium of claim 15, wherein the peeling layer is made of an organic material.

23. The method of manufacturing a master of an optical information recording medium of claim 22, wherein the thickness of the peeling layer is 60 nm or less.

24. A master of an optical information recording medium, which is manufactured by the method of claim 1.

25. A master of an optical information recording medium, comprising:
a substrate;
a pattern of pits or a groove on a resist which is formed on the substrate; and
a isolating layer which is formed on the pattern of pits or a groove.

26. A method of manufacturing a stamper of an optical information recording medium using the master of claim 25, comprising:
forming a conductive film on the master;
forming a metal layer on the conductive film; and
peeling the metal layer, or the metal layer and the conductive film, from the master.

27. A stamper of an optical information recording medium, which is manufactured by the method of manufacturing a stamper of an optical information recording medium of claim 26.

28. An optical information recording medium, which is manufactured by using the stamper of an optical information recording medium of claim 27.
